(19) United States
(12) Patent Application Publication
(10) Pub. No.: US 2024/0175116 A1
(43) Pub. Date: May 30, 2024

(54) CR-SI FILM

(71) Applicant: TOSOH CORPORATION, Shunan-shi, Yamaguchi (JP)

(72) Inventors: Hiroyuki HARA, Ayase-shi, Kanagawa (JP); Masami MESUDA, Ayase-shi, Kanagawa (JP); Ayaka MASUDA, Ayase-shi, Kanagawa (JP)

(21) Appl. No.: 18/552,439

(22) PCT Filed: Mar. 25, 2022
(86) PCT No.: PCT/JP2022/014684

§ 371 Date: Sep. 26, 2023

(30) Foreign Application Priority Data
Mar. 29, 2021 (JP) 2021-054735

(51) Int. Cl. C23C 14/06; C23C 14/34

(52) U.S. Cl. CPC C23C 14/0682; C23C 14/3407

(57) ABSTRACT

A Cr—Si film contains chromium (Cr) and silicon (Si). In the Cr—Si film, a composition range of the film is Cr/(Cr+Si)=0.25 to 0.75, and absolute values of TCR in increments of 10° C. in a temperature range of 40° C. to 150° C. are each 0 ppm/° C. or more and 100 ppm/° C. or less.

### TECHNICAL FIELD

The present invention relates to a Cr—Si film that has a small absolute value of TCR and that undergoes little change in TCR at each temperature.

### BACKGROUND ART

In recent years, Cr—Si materials (silicides) such as CrSi₂ have been used as films (Cr—Si films) in, for example, semiconductors and solar cells because of their properties. Since Cr—Si materials can have semiconductor properties and metal properties in accordance with the state of the crystal phase, they have low temperature change of resistivity (TCR) and are used in various sensors. The various sensors are used in environments where the temperature changes in a range from room temperature to high temperature (150° C. or lower), for example, in electrical appliances and automobiles. Therefore, from the viewpoint of improving detection accuracy, it is desirable that a Cr—Si film have the same resistivity at all temperatures from room temperature to high temperature (that is, it is desirable that a variation in the value of resistivity be small in a temperature range from room temperature to high temperature).

For example, Patent Literature 1 discloses that a characteristic (tendency) of a change in the sheet resistance after heat treatment changes depending on the composition ratio of Cr and Si. Specifically, it is reported that, in a Cr—Si film formed using a target containing Cr in an amount of 40 wt % or more, the resistance has high thermal stability even when N₂ is not added, and that, in a Cr—Si film formed using a target containing Cr in an amount of 30 wt % or less, the variation in the resistance is large under the condition in which N₂ is not added, but this variation can be improved by adding N₂. However, Patent Literature 1 does not determine a composition range in which TCR can be made close to zero (that is, the absolute value of TCR can be decreased).

In Patent Literature 2, although physical properties of a film formed from a Cr—Si sputtering target containing Cr in an amount of 30 wt % are measured, only a resistivity at 20° C. and a resistivity at 120° C. are measured for TCR. However, a typical Cr—Si film is known to exhibit a resistivity change having a curved form with respect to the temperature, and thus TCR determined from only two points at 20° C. and 120° C. is insufficient in terms of evaluation for use as an actual sensor, and the behavior of the change in TCR with respect to the temperature change cannot be grasped.

### CITATION LIST

### Patent Literature

PTL 1: Japanese Unexamined Patent Publication No. 2010-278479
PTL 2: Japanese Unexamined Patent Publication No. 2002-367803

### SUMMARY OF INVENTION

### Technical Problem

An object of the present invention is to provide a Cr—Si film that contains chromium (Cr) and silicon (Si), that has a small absolute value of TCR, and that undergoes little change in TCR at each temperature.

### Solution to Problem

The inventors of the present invention have conducted studies on Cr—Si films containing chromium (Cr) and silicon (Si) and consequently found that a Cr—Si film that has a small TCR and undergoes little change in TCR at each temperature is obtained by optimizing the composition ratio. This finding led to the completion of the present invention.

That is, the present invention is described in the claims, and the gist of the present invention is as follows.
(1) A Cr—Si film containing chromium (Cr) and silicon (Si), in which a composition range of the film is Cr/(Cr+Si)=0.25 to 0.75, and absolute values of TCR in increments of 10° C. in a temperature range of 40° C. to 150° C. are each 0 ppm/° C. or more and 100 ppm/° C. or less.
(2) The Cr—Si film according to (1), in which a difference between a maximum value and a minimum value of TCR in increments of 10° C. in the temperature range is 100 ppm/° C. or less.
(3) The Cr—Si film according to (1) or (2), in which the absolute values of TCR in increments of 10° C. in the temperature range are each 0 ppm/° C. or more and 50 ppm/° C. or less.
(4) The Cr—Si film according to any one of (1) to (3), in which an absolute value of an average TCR in increments of 10° C. in the temperature range is 0 ppm/° C. or more and 50 ppm/° C. or less.
(5) The Cr—Si film according to any one of (1) to (4), in which the composition range of the film is Cr/(Cr+Si)=0.3 to 0.5.
(6) The Cr—Si film according to any one of (1) to (5), further containing nitrogen (N).
(7) The Cr—Si film according to (6), in which Si−N=25 to 75 wt %.
(8) A method for producing the Cr—Si film according to any one of (1) to (7), the method including forming a film using a sputtering target containing chromium and silicon as a main component by a sputter method.
(9) The method for producing the Cr—Si film according to (8), further including subjecting a Cr—Si film formed by the sputter method to heat treatment in a non-oxygen atmosphere at 800° C. or lower.

### Advantageous Effects of Invention

Since the Cr—Si film according to the present invention has a small absolute value of TCR in a temperature range of 40° C. to 150° C., when used as a resistor, the Cr—Si film exhibits a stable resistivity even in any temperature zone within the above temperature range. Thus, a sensor with high accuracy can be provided.

### BRIEF DESCRIPTION OF DRAWINGS

FIG. 1 is a graph showing the relationship between the resistivity and the temperature of a Cr—Si film of Example 1.

FIG. 2 is a graph showing the relationship between the resistivity and the temperature of a Cr—Si film of Comparative Example 1.

### DESCRIPTION OF EMBODIMENTS

The present invention will be described in detail below. In the present description, “to” between two numerical values represents a range including the two numerical values given as the upper and lower limits, and, for example, “30° C. to 150° C.” or “30 to 150° C.” means “30° C. or higher and 150° C. or lower”. In the present description, “wt %” represents “mass %”.

The present invention provides a Cr—Si film containing chromium (Cr) and silicon (Si), in which a composition range of the film is Cr/(Cr+Si)=0.25 to 0.75, and absolute values of TCR in increments of 10° C. in a temperature range of 40° C. to 150° C. are each 0 ppm/° C. or more and 100 ppm/° C. or less.

The present invention relates to a Cr—Si film and provides a so-called silicide film containing chromium silicide as a matrix (parent phase or main phase), and furthermore, a chromium silicide film. The Cr—Si film according to the present invention may contain an element other than Cr and Si as long as the Cr—Si film contains chromium silicide as a matrix.

The composition range of the Cr—Si film according to the present invention is Cr/(Cr+Si)=0.25 to 0.75. Cr/(Cr+Si) is preferably 0.3 to 0.7, particularly preferably 0.3 to 0.5. A Cr ratio (that is, Cr/(Cr+Si)) of more than 0.75 increases TCR, and a Cr ratio of less than 0.25 decreases TCR. In Cr/(Cr+Si), “Cr” represents a Cr content (wt %), and “Si” represents a Si content (wt %).

The absolute values of TCR of the Cr—Si film according to the present invention in increments of 10° C. in a temperature range of 40° C. to 150° C. are each 0 ppm/° C. or more and 100 ppm/° C. or less. The “TCR in increments of 10° C. in a temperature range of 40° C. to 150° C. (hereinafter, also referred to as “TCRₜ”, and “TCRₜ at 100° C.” and the like are also referred to as “TCR₁₀₀” and the like)” is the absolute value of TCR at a temperature of 40° C., 50° C., 60° C., 70° C., 80° C., 90° C., 100° C., 110° C., 120° C., 130° C., 140° C., or 150° C.

TCR (ppm/° C.) is a value calculated by the following formula from a resistivity R (Ω·cm) at each temperature of a Cr—Si film, a resistivity R₃₀ (Ω·cm) at 30° C., and a measurement temperature T (° C.).

TCR=(R−R₃)/(R₃₀×(T−30))×10⁶

The “resistivity R at each temperature” refers to a resistivity at each measurement temperature of 30° C., 40° C., 50° C., 60° C., 70° C., 80° C., 90° C., 100° C., 110° C., 120° C. 130° C., 140° C., or 150° C., and the resistivity R at 30° C. and the like are denoted by “R₃₀” and the like. Each TCRₜ is preferably 0 ppm/° C. or more and 50 ppm/° C. or less. When TCRₜ is within this range, a significant variation in the resistance value depending on the temperature is unlikely to occur, and thus a sensor with high detection accuracy is likely to be obtained.

The difference between the maximum value and the minimum value of TCR of the Cr—Si film according to the present invention in increments of 10° C. in a range of 40° C. to 150° C. is preferably 100 ppm/° C. or less, more preferably 50 ppm/° C. or less, and still more preferably 20 ppm/° C. or less. The smaller the difference between the maximum value and the minimum value, the smaller the amount of change in the resistivity in a range of 30° C. to 150° C. Thus, a high performance can be exhibited as a resistor in the entire temperature range within this range. The difference between the maximum value and the minimum value (=maximum value−minimum value) of TCR is, for example, 0 ppm/° C. or more, 1 ppm/° C. or more, or 5 ppm or more/° C.

The “difference between the maximum value and the minimum value of TCR” refers to a difference between the maximum value and the minimum value in TCR₄₀ to TCR₁₅₀.

An average TCR of the Cr—Si film according to the present invention is preferably within ±50 ppm/° C. (that is, the absolute value of the average TCR is preferably 0 ppm/° C. or more and 50 ppm/° C. or less). The average TCR is more preferably within ±30 ppm/° C. (that is, the absolute value of the average TCR is more preferably 0 ppm/° C. or more and 30 ppm/° C. or less), still more preferably within 10 ppm/° C. (that is, the absolute value of the average TCR is still more preferably 0 ppm/° C. or more and 10 ppm/° C. or less). A small absolute value of the average TCR indicates that the range of the resistance is less likely to change depending on the temperature (that is, the change in the resistivity depending on the temperature is small). Accordingly, a Cr—Si film having a small absolute value of the average TCR exhibits a high performance as a resistor. The “average TCR” refers to the arithmetic mean of the TCR₄₀ to the TCR₁₅₀.

The resistivity at 30° C. (R₃₀; Ω·cm) of the Cr—Si film according to the present invention is, for example, 1.0×10⁻⁶ Ω·cm or more, 1.0×10⁻⁵ Ω·cm or more, 1.0×10⁻⁴ Ω·cm or more, or 1.0×10⁻³ Ω·cm or more, and 10 Ω·cm or less, 1.0 Ω·cm or less, or 1.0×10⁻¹ Ω·cm or less. The resistivity of the film can be measured using, for example, a model 8403 AC/DC Hall measurement system (manufactured by TOYO Corporation).

The Cr—Si film according to the present invention preferably has a small thickness. A Cr—Si film is used as a resistor of a high-resistance portion; therefore, as the film thickness decreases, the sheet resistance increases. However, if the film thickness is excessively small, the film has no continuity and becomes an insulating film. Accordingly, the film thickness is preferably 1 to 500 nm, more preferably 1 to 300 nm, and still more preferably 1 to 150 nm. The film thickness is preferably 50 nm or more, or 80 nm or more, and 150 nm or less, or 120 nm or less because a thin film suitable for a resistor or the like tends to be obtained.

The Cr—Si film according to the present invention preferably further contains nitrogen (N). With regard to the nitrogen content (wt %), the difference from the silicon (Si) content (wt %) is preferably Si−N (=(Si content)−(N content))=25 to 75 wt %, more preferably 25 to 45 wt %, and particularly preferably 25 to 40 wt %. When Si−N is 75 wt % or less, the difference between the maximum value and the minimum value of TCR is less likely to increase. When Si−N is 25 wt % or more, the Cr—Si film serves as a nitride film, and thus the absolute value of TCR is less likely to increase.

The Cr—Si film according to the present invention may contain metal impurities such as Fe and Al and the content (wt %) of the metal impurities is preferably as low as possible. The metal impurities are metal elements other than Cr contained in the Cr—Si film according to the present invention. When the amount of metal impurities is small, a variation in TCR tends to decrease, and TCR is likely to be small. The total amount of metal impurities is preferably 1 wt % or less, more preferably 0.5 wt % or less, and still more preferably 0.1 wt % or less. The total amount of metal impurities is, for example, 0 wt/o or more, 0.001 wt % or more, 0.005 Wt % or more, or 0.01 wt % or more.

Next, methods for producing the Cr—Si film according to the present invention will be described.

A method for producing the Cr—Si film according to the present invention is a method including forming a film using a sputtering target containing chromium and silicon as a main component by a sputter method (a sputtering method), and furthermore, the Cr—Si film can be produced by a method including forming a film using a sputtering target containing chromium and silicon as a main component by a sputter method, and subsequently performing heat treatment in a non-oxygen atmosphere at 800° C. or lower. Alternatively, the Cr—Si film according to the present invention can be produced by a method including forming a film simultaneously using a sputtering target of chromium and a sputtering target of silicon by a sputter method. Preferably, a method for producing the Cr—Si film includes a step of forming a film by a sputter method using a sputtering target containing chromium and silicon as a main component. The “main component” refers to a component having a content of 99 wt % or more. More specifically, the phrase “containing chromium and silicon as a main component” means that the total of the mass of chromium and the mass of silicon accounts for 99 wt % or more of the total mass of the sputtering target. More preferably, an alloy of chromium and silicon accounts for 99 wt % or more of the sputtering target.

The sputtering target used in the production method according to the present invention has a purity of 99% or more and is preferably a sputtering target with a purity of 99.5% or more, and the amount of oxygen in the sputtering target is preferably small. The “purity” means the content of the main component in the sputtering target, and “%” that is the unit of the purity represents “wt %”. A method for producing such a sputtering target is not limited, but an example thereof is described below.

### <Process for Producing Sputtering Target>

The sputtering target can be produced by preparing (that is, mixing) a Cr powder and a Si powder so as to satisfy a specific composition range, for example, a composition that is the same as a composition of an intended Cr—Si film, to obtain a mixed powder; and subjecting the mixed powder to a method such as a powder-metallurgical method or a melting method. Specifically, the sputtering target is obtained by, for example, a production method including an alloy powder preparation step of preparing an alloy powder using an alloy powder, a gas atomization method, a quenching roll (strip casting)method, or an arc melting method; and a sintering step of sintering the alloy powder. The alloy powder is preferably a powder prepared by a gas atomization method.

### (Alloy Powder Preparation Step)

Pure chromium (metal chromium) and pure silicon (metal silicon) are used as raw materials used in the alloy powder preparation step. The purities of pure chromium and pure silicon are each preferably 99.9 mass % or more (3N or more), more preferably 99.99 mass % or more (4N or more), and still more preferably 99.999 mass % or more (5N or more).

In the raw material preparation step, the raw material powder is preferably processed by a gas atomization method. In the gas atomization method, pure chromium and pure silicon are melted by high-frequency induction melting at a melting temperature to obtain a melt, and while the melt is dropped, a high-pressure gas is blown to the melt to thereby obtain an alloy powder including a fine crystalline microstructure.

The temperature of the melt in the gas atomization method is preferably the melting temperature+50° C. or higher and the melting temperature+300° C. or lower, more preferably the melting temperature+100° C. or higher and the melting temperature+250° C. or lower. The “melting temperature” as used herein refers to a temperature at which both pure chromium and pure silicon melt and is, for example, 1,300° C. or higher and 1.500° C. or lower.

### (Sintering Step)

The alloy powder is sintered to obtain the sputtering target. Sintering is preferably performed by pressure sintering such as hot pressing. The pressure (sintering pressure) applied to the alloy powder in pressure sintering is 1 MPa or more, and 50 MPa or less, preferably 20 MPa or less, more preferably 10 MPa or less.

The sintering temperature in the sintering step is, for example, 1,100° C. or higher and 1,400° C. or lower. The time (sintering time) during which the above sintering pressure and the above sintering temperature are held is, for example, one hour or more and five hours or less.

The atmosphere of sintering is not particularly limited as long as oxidation of a Cr—Si sintered body is suppressed in the atmosphere. To further suppress oxidation of a Cr—Si sintered body, the atmosphere in the sintering step is preferably a vacuum or an inert atmosphere, and furthermore, a vacuum atmosphere or a reduced-pressure atmosphere.

The sputtering target is obtained through the above steps. If the resulting sputtering target contains impurities in a large amount, physical properties of a film are adversely affected. Therefore, it is preferable to obtain a sputtering target with a purity of 99.5% or more. The amount of oxygen in the sputtering target is preferably small. A large amount of oxygen may cause the generation of particles, resulting in deterioration of the production yield.

Hereinafter, each step of an example of a method for producing a Cr—Si film according to the present invention will be described.

### (2) Sputtering Step

The film is obtained by forming a film using the above-described sputtering target by a sputter method, that is, by performing a sputter method using the above-described sputtering target. As the sputtering method (sputter method), at least one selected from the group consisting of a DC sputtering method, an RF sputtering method, an AC sputtering method, a DC magnetron sputtering method, an RF magnetron sputtering method, and an ion-beam sputtering method can be appropriately selected. From the viewpoint that the film can be uniformly formed on a large area and at a high speed, the sputtering method is preferably a DC magnetron sputtering method or an RF magnetron sputtering method.

The sputtering power is preferably 0.6 W/cm² or more and 10 W/cm² or less. At a sputtering power of 0.6 W/cm² or more, the film formation rate is high, and productivity is unlikely to decrease. On the other hand, at a sputtering power of 10 W/cm² or less, the load on the target is small, and the possibility of cracking decreases.

During sputtering, the film is formed using argon gas and nitrogen gas as introduction gas, but, oxygen gas, hydrogen gas or the like may be used as needed.

### (3) Heat Treatment Step

The obtained film may be subjected to heat treatment under an appropriate temperature condition. In this case, the absolute value of TCR can be further decreased. The temperature of the heat treatment step is preferably 800° C. or lower, or 700° C. or lower, and preferably 150° C. or higher, 200° C. or higher, 300° C. or higher, or 500° C. or higher. When the temperature of the heat treatment step is 800° C. or lower, the production efficiency of the film is unlikely to decrease. On the other hand, when the temperature of the heat treatment step is 150° C. or higher, the absolute value of TCR is likely to be small. The time of the heat treatment is, for example, 0.5 hours or more and 10 hours or less.

The heat treatment preferably includes heating in a non-oxygen atmosphere. In an oxygen-containing atmosphere, oxidation proceeds with heating, and physical properties of the film deteriorate. Therefore, the heat treatment is preferably performed in a non-oxygen atmosphere. The “non-oxygen atmosphere” refers to an atmosphere free of oxygen and is specifically, for example, at least one selected from the group consisting of a vacuum atmosphere, an argon atmosphere, and a nitrogen atmosphere, preferably a vacuum atmosphere, and particularly preferably a vacuum atmosphere of 10 Pa or less.

Other embodiments of the present invention include the following.
(1) A Cr—Si film containing chromium (Cr) and silicon (Si), in which a composition range of the film is Cr/(Cr+Si)=0.25 to 0.75, and an absolute value of an average TCR is ±50 ppm or less.
(2) The Cr—Si film according to (1), further containing nitrogen (N), in which Si−N=25 to 75 wt %.
(3) The Cr—Si film according to (1) or (2), in which a difference between a maximum value and a minimum value of TCR in increments of 10° C. degrees in a range of 30° C. to 150° C. is 100 ppm or less.
(4) A method for producing the Cr—Si film according to any one of (1) to (3), the method including forming a film using a sputtering target containing chromium and silicon as a main component by a sputter method, and subsequently performing heat treatment in a non-oxygen atmosphere at 800° C. or lower.

### EXAMPLES

Hereinafter, the present invention will be described in further detail with reference to Examples; however, the present invention is not limited to these. Note that measurements in Examples and Comparative Examples were performed as follows.

### (1) Film Formation Conditions for Cr—Si Film

### <Preparation of Sputtering Target>

A Cr powder with a purity of 4N and a Si powder with a purity of 5N were mixed so as to satisfy the composition of a sputtering target in Table 1 and melted in a carbon crucible at a melting temperature of 1,600° C. to obtain a melt at 1,600° C. Note that the target composition in Table 1 is the same as the composition of the powders charged. A Cr—Si alloy powder was obtained from the melt by a gas atomization method. The resulting Cr—Si alloy powder was placed in a carbon crucible and pressure-sintered by hot pressing under the following conditions to prepare a Cr—Si sintered body having a desired composition.

### (Sintering Conditions)

Sintering furnace: Hot-press furnace
Temperature increase rate: 200° C./hour
Temperature increase atmosphere: Vacuum (5 Pa or less)
Sintering temperature: 1,250° C.
Sintering pressure: 20 MPa
Sintering time: 3 hours

The resulting sintered body was machined into a sputtering target with a diameter of four inches.

### <Sputtering Step>

Film formation was performed by a sputtering method using each sputtering target obtained to prepare Cr—Si films of Examples and Comparative Examples having desired compositions. The Cr—Si films of Examples and Comparative Examples were formed under the conditions shown in Table 1. The detailed film formation conditions are described below.

### (Sputtering Conditions)

Apparatus: DC magnetron sputtering apparatus (manufactured by ULVAC, Inc.)
Magnetic field strength: 1.000 Gauss (directly on target, horizontal component)
Distance between target and substrate: 90 mm
Substrate temperature: Room temperature (about 25° C.)
Type of introduction gas (sputtering atmosphere): Argon (Ar), or argon and nitrogen (N₂)
Introduction gas partial pressure: Sputtering was performed at the nitrogen partial pressure (N₂/(Ar+N₂)) in Table 1.
Substrate used: Glass substrate (Corning Incorporated, Eagle XG), 0.8 mm in thickness
Sputtering power: 200 W (2.5 W/cm²)
Target film thickness: 100 nm

Note that, in Table 1, the nitrogen partial pressure (N₂/(Ar+N₂)) is indicated as a ratio (%) of N₂ to the total amount of Ar+N₂ defined as 100%.

(Post-Treatment Conditions after Film Formation)

The Cr—Si films formed on the substrates were each subjected to heat treatment in a vacuum for 60 minutes at the heat-treatment temperature shown in Table 2.

The compositions, crystallinity, and electrical properties of each of the films were measured by the following methods.

### (Composition of Film)

The composition of the film was quantified by an RBS method (Rutherford backscattering spectrometry) using a typical measurement apparatus (manufactured by Eurofins EAG, RBS-400 analytical end station).

### (Resistivity)

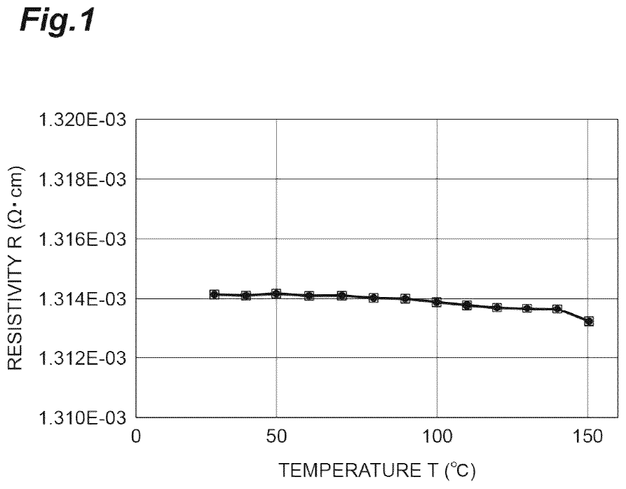

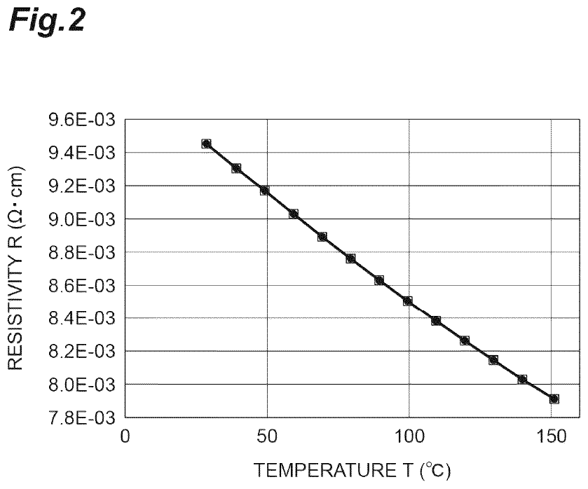

The resistivity of the film was measured using a model 8403 AC/DC Hall measurement system (manufactured by TOYO Corporation). FIGS. 1 and 2 show the relationships between the resistivity and the temperature of Example 1 and Comparative Example 1, respectively, described below.

### (2) Methods for Calculating TCR and Average TCR

The resistivities (Ω·cm) of the film were measured in increments of 10° C. from 30° C. to 150° C. using the model 8403 AC/DC Hall measurement system (manufactured by TOYO Corporation) to determine resistivities R (R₃₀ to R₁₅₀). The TCR was calculated in the range of 40° C. to 150° C. by the following formula from the resistivity R (Ω·cm) at each temperature, the resistivity R₃₀ (Ω·cm) at 30° C., and each temperature T (° C.).

TCR (ppm/° C.)=(R−R₃₀)/(R₃₀×(T−30))×10⁶

The arithmetic mean of the values of TCR determined in the range of 40° C. to 150° C. was used as the average TCR.

### (3) Method for Calculating Difference Between Maximum Value and Minimum Value of TCR

For the TCR in the range of 40° C. to 150° C. determined in (2), the difference between the maximum value and the minimum value was determined.

### Example 1

A Cr—Si film was formed by a sputtering method under the film formation conditions in Table 1 using the sputtering target having the Cr—Si composition (target composition) in Table 1. The resulting Cr—Si film was subjected to heat treatment under a vacuum (5 Pa or less) at the treatment temperature in Table 2. The average TCR, the maximum value of TCR in the temperatures, the minimum value of TCR in the temperatures, the maximum value−the minimum value of TCR, and the resistivity at 30° C. of the resulting Cr—Si film were measured. The results are shown in Table 2.

### Examples 2, 3, 6, 8, and 9

Cr—Si films were each produced under the same conditions as those in Example 1 except that the composition of the sputtering target and the film formation conditions (atmosphere gas during film formation (introduction gas), N₂/(Ar+N₂), and the film thickness) were changed to the composition of the sputtering target and the film formation conditions in Table 1, and the heat-treatment temperature of the Cr—Si film was changed to the heat-treatment temperature (treatment temperature in Table 2) of the Cr—Si film. The average TCR, the maximum value of TCR in the temperatures, the minimum value of TCR in the temperatures, the maximum value−the minimum value of TCR, and the resistivity at 30° C. of each of the resulting Cr—Si films were measured. The results are shown in Table 2.

### Example 4

A Cr—Si film was obtained under the same conditions as those in Example 1 except that, in the preparation of the sputtering target, the temperature of the melt in the gas atomization method was changed to 1,700° C. and the sintering temperature in the preparation of the sintered body was changed to 1,350° C., the composition of the sputtering target and the film formation conditions were changed to the composition of the sputtering target and the film formation conditions in Table 1, and heat treatment after the film formation was not performed.

### Example 5

A Cr—Si film was obtained under the same conditions as those in Example 1 except that, in the preparation of the sputtering target, the temperature of the melt in the gas atomization method was changed to 1,700° C. and the sintering temperature in the preparation of the sintered body was changed to 1,350° C. the composition of the sputtering target and the film formation conditions were changed to the composition of the sputtering target and the film formation conditions in Table 1, and the heat-treatment temperature of the Cr—Si film was changed to the heat-treatment temperature (treatment temperature in Table 2) of the Cr—Si film.

### Example 7

A Cr—Si film was obtained in the same manner as in Example 1 except that the film was formed by sputtering under the film formation conditions in Table 1, and heat treatment after the film formation was not performed.

### Comparative Examples 1, 2, and 4

Cr—Si films were each produced under the same conditions as those in Example 1 except that the composition of the sputtering target and the film formation conditions were changed to the composition of the sputtering target and the film formation conditions in Table 1, and the heat-treatment temperature of the Cr—Si film after the film formation was changed to the treatment temperature in Table 2. The average TCR, the maximum value of TCR in the temperatures, the minimum value of TCR in the temperatures, the maximum value−the minimum value of TCR, and the resistivity at 30° C. of each of the resulting Cr—Si films were measured. The results are shown in Table 2.

### Comparative Example 3

A Cr—Si film was produced under the same conditions as those in Example 1 except that, in the preparation of the sputtering target, the temperature of the melt in the gas atomization method was changed to 1,730° C. and the sintering temperature in the preparation of the sintered body was changed to 1,350° C. the composition of the sputtering target and the film formation conditions were changed to the composition of the sputtering target and the film formation conditions in Table 1, and the heat-treatment temperature of the Cr—Si film after the film formation was changed to the treatment temperature in Table 2. The average TCR, the maximum value of TCR in the temperatures, the minimum value of TCR in the temperatures, the maximum value−the minimum value of TCR, and the resistivity at 30° C. of the resulting Cr—Si film were measured. The results are shown in Table 2.

TABLE 1

| | | | Film formation conditions | | |
|---|---|---|---|---|---|
| | Target composition | | | | Film |
| | Cr | Si | Introduction | N₂/(Ar + | thickness |
| | (wt %) | (wt %) | gas | N₂) (%) | (nm) |
| Example 1 | 42 | 58 | Ar, N₂ | 10 | 102 |
| Example 2 | 42 | 58 | Ar, N₂ | 5 | 100 |
| Example 3 | 42 | 58 | Ar | 0 | 97 |
| Example 4 | 60 | 40 | Ar | 0 | 96 |
| Example 5 | 60 | 40 | Ar, N₂ | 10 | 93 |
| Example 6 | 25 | 75 | Ar | 0 | 95 |
| Example 7 | 66 | 34 | Ar | 0 | 93 |
| Example 8 | 33 | 67 | Ar | 0 | 92 |
| Example 9 | 33 | 67 | Ar, N₂ | 10 | 94 |
| Comparative | 18 | 82 | Ar | 0 | 101 |
| Example 1 | | | | | |
| Comparative | 18 | 82 | Ar, N₂ | 10 | 97 |
| Example 2 | | | | | |
| Comparative | 75 | 25 | Ar | 0 | 96 |
| Example 3 | | | | | |
| Comparative | 42 | 58 | Ar, N₂ | 15 | 99 |
| Example 4 | | | | | |

TABLE 2

| | | | | | | | | Maximum | Minimum | Maximum | |
|---|---|---|---|---|---|---|---|---|---|---|---|
| | | | | Cr/ | | | | value | value | value − | |
| | | | | (Cr + Si) | Si − | Treatment | Average | of TCR in | of TCR in | minimum | Resistivity |
| | Cr | Si | N | (mass | N | temperature | TCR | temperatures | temperatures | value of TCR | at 30° C. |
| | (wt %) | (wt %) | (wt %) | ratio) | (wt %) | (° C.) | (ppm/° C.) | (ppm/° C.) | (ppm/° C.) | (ppm/° C.) | (Ω · cm) |
| Example 1 | 39.5 | 46.2 | 14.3 | 0.46 | 31.9 | 580 | −2.5 | 1.0 | −5.8 | 6.8 | 1.3E−03 |
| Example 2 | 42.5 | 50.3 | 7.2 | 0.46 | 43.1 | 480 | −40.3 | −25.7 | −52.9 | 27.2 | 8.0E−04 |
| Example 3 | 46.6 | 53.4 | 0.0 | 0.47 | 53.4 | 230 | 23.7 | 67.0 | −28.0 | 95.0 | 1.1E−03 |
| Example 4 | 66.2 | 33.8 | 0.0 | 0.66 | 33.8 | — | 6.4 | 12.6 | 1.5 | 11.1 | 2.1E−04 |
| Example 5 | 61.9 | 31.6 | 6.5 | 0.66 | 25.1 | 530 | −5.1 | −0.4 | −10.6 | 10.2 | 7.3E−04 |
| Example 6 | 27.6 | 72.4 | 0.0 | 0.28 | 72.4 | 600 | −6.2 | 37.3 | −60.1 | 97.4 | 3.8E−02 |
| Example 7 | 71.2 | 28.8 | 0.0 | 0.71 | 28.8 | — | 31.5 | 85.2 | 24.5 | 60.7 | 1.8E−04 |
| Example 8 | 37.3 | 62.7 | 0.0 | 0.37 | 62.7 | 570 | −38.1 | 8.8 | −91.0 | 99.8 | 5.3E−03 |
| Example 9 | 34.0 | 57.0 | 9.0 | 0.37 | 48.0 | 660 | −1.4 | 5.6 | −17.2 | 22.8 | 3.6E−03 |
| Comparative | 20.9 | 79.1 | 0.0 | 0.21 | 79.1 | 600 | −1410 | −1331 | −1470 | 139 | 9.5E−03 |
| Example 1 | | | | | | | | | | | |
| Comparative | 16.0 | 60.4 | 23.6 | 0.21 | 36.8 | 600 | −1952 | −1687 | −2160 | 473 | 1.1E−01 |
| Example 2 | | | | | | | | | | | |
| Comparative | 81.3 | 18.8 | 0.0 | 0.81 | 18.8 | — | 92.4 | 219.0 | 76 | 143 | 1.2E−04 |
| Example 3 | | | | | | | | | | | |
| Comparative | 35.5 | 42.0 | 22.5 | 0.46 | 19.5 | 600 | −281 | −260 | −298 | 38 | 7.2E−02 |
| Example 4 | | | | | | | | | | | |

In the table, the symbol “-” in the column of the treatment temperature indicates that heat treatment was not performed. In the table and FIGS. 1 and 2, the expression “∘∘E−xx” of the resistivity means a value obtained by multiplying ∘∘ by 10 to the negative xxth power. For example, “1.3E-03” represents 1.3×10\hat{ }(−3) and means a value obtained by multiplying 1.3 by 10 to the negative third power.

The Cr—Si films according to the present invention each have a small absolute value of TCR, a small absolute value of the average TCR, and a small difference between the maximum value and the minimum value of TCR and have excellent properties as a resistor.

1. A Cr—Si film comprising chromium (Cr) and silicon (Si), wherein a composition range of the film is Cr/(Cr+Si)=0.25 to 0.75, and absolute values of TCR in increments of 10° C. in a temperature range of 40° C. to 150° C. are each 0 ppm/° C. or more and 100 ppm/° C. or less.

2. The Cr—Si film according to claim 1, wherein a difference between a maximum value and a minimum value of TCR in increments of 10° C. in the temperature range is 100 ppm/° C. or less.

3. The Cr—Si film according to claim 1, wherein the absolute values of TCR in increments of 10° C. in the temperature range are each 0 ppm/° C. or more and 50 ppm/° C. or less.

4. The Cr—Si film according to claim 1, wherein an absolute value of an average TCR in increments of 10° C. in the temperature range is 0 ppm/° C. or more and 50 ppm/° C. or less.

5. The Cr—Si film according to claim 1, wherein the composition range of the film is Cr/(Cr+Si)=0.3 to 0.5.

6. The Cr—Si film according to claim 1, further comprising nitrogen (N).

7. The Cr—Si film according to claim 6, wherein Si−N=25 to 75 wt %.

8. A method for producing the Cr—Si film according to claim 1, the method comprising forming a film using a sputtering target containing chromium and silicon as a main component by a sputter method.

9. The method for producing the Cr—Si film according to claim 8, further comprising subjecting a Cr—Si film formed by a sputtering method to heat treatment in a non-oxygen atmosphere at 800° C. or lower.
